(19) United States
(12) Patent Application Publication
(10) Pub. No.: US 2016/0351809 A1
(43) Pub. Date: Dec. 1, 2016

(54) WHITE-LIGHT OLED DISPLAY PANEL AND THE SERIALLY-CONNECTED WHITE-LIGHT OLED THEREOF

(71) Applicant: Shenzhen Chian Star Optoelectronics Technology Co., Ltd., Shenzhen , Guangdong (CN)

(72) Inventors: Xianjie LI, Shenzhen, Guangdong (CN); Qinghua ZOU, Shenzhen, Guangdong (CN)

(73) Assignee: Shenzhen China Star Optoelectronics Technology Co., Ltd., Shenzhen, Guangdong (CN)

(21) Appl. No.: 14/404,709

(22) PCT Filed: Nov. 25, 2014
(86) PCT No.: PCT/CN2014/092126

§ 371 Date: Dec. 1, 2014

(30) Foreign Application Priority Data
Nov. 18, 2014 (CN) 201410660302.1

(51) Int. Cl. H01L 51/00; H01L 51/52; H01L 27/32; H01L 51/50

(52) U.S. Cl. CPC H01L 51/006; H01L 51/504; H01L 51/5206; H01L 51/5221; H01L 27/3204; H01L 51/005; H01L 51/0072; H01L 51/0061; H01L 51/0085; H01L 51/5076; H01L 2251/308; H01L 2251/558; H01L 51/5012; H01L 51/5056; H01L 2251/301; H01L 2251/303; H01L 51/0058

(57) ABSTRACT

A serially-connected white-light OLED includes an anode, a first light emitting unit, a middle charge generating layer, a second light emitting unit, and a cathode serially connected and stacked in turn. The first light emitting unit is configured to emit blue light and the second light emitting layer is configured to emit yellow light, or both of the first and second light emitting unit is configured to emit white light. The middle electron transport layer comprises Bphen doped with reactive metal having a work function lower than 3 eV so as to absorb electron transport material within the middle electron transport layer having a peak position larger than 490 nm or smaller than 440 nm. In this way, the absorbed blue light is decreased so as to implement the cool white.

### BACKGROUND OF THE INVENTION

1. Field of the Invention

The present disclosure relates to liquid crystal display technology, and more particularly to a serially-connected white-light OLED and the white-light OLED display panel adopting the serially-connected white-light OLED.

2. Discussion of the Related Art

Organic Light-Emitting Diodes (OLEDs) typically are characterized by attributes including self-illuminating, high color saturation, and high contrastness, and thus is the main trend of next technology of tablet display and flexible display. Currently, small-scale OLED display panels have been adopted by cellular phones and tablets, and the cost of the small-sized OLED display panels is close to that of the liquid crystal display (LCD). However, the large-scale OLED display panels still have disadvantages, such as high cost and short life cycle.

Currently, the best candidate for being adopted by large-scale OLED display panels is the WOLED (White-light OLED) and the CF substrate, which has the potential for greatly enhancing the product quality. Usually, the adopted WOLED is of serially-connected type, in which the component efficiency and the life cycle can be doubled. How to enhance the blue light of the serially-connected white-light OLED to implement cool white is a critical issue.

### SUMMARY

The white-light OLED display panel and the serially-connected white-light OLED enhance the blue light of the serially-connected white-light OLED so as to implement the cool white.

In one aspect, a serially-connected white-light OLED includes: an anode, a first light emitting unit, a middle charge generating layer, a second light emitting unit, and a cathode serially connected and stacked in turn; the first light emitting unit being configured to emit blue light and the second light emitting layer being configured to emit yellow light, or both of the first and second light emitting unit being configured to emit white light; the middle electron transport layer comprises Bphen doped with reactive metal having a work function lower than 3 eV so as to absorb electron transport material within the middle electron transport layer having a peak position larger than 490 nm or smaller than 440 nm; the first light emitting unit comprises a first hole transport layer, a first light emitting layer, and a first electron transport layer; the second light emitting unit comprises a second hole transport layer, a second light emitting layer, and a second electron transport layer; the anode comprises ITO with a thickness equaling to 70 nm; the first hole transport layer comprises NPB with the thickness equaling to 60 nm; the first light emitting layer comprises DPVBi with the thickness equaling to 25 nm; the first electron transport layer comprises Bphen with the thickness equaling to 10 nm; the middle electron transport layer comprises Bphen doped with Li, Na, K, Ru or Cs with the thickness equaling to 10 nm; the connecting layer comprises one or at least one of MoO₃, WO₃, V₂O₅, ReO₃ with the thickness equaling to 20 nm; the middle hole transport layer comprises NPB with the thickness equaling to 20 nm; the second hole transport layer comprises TCTA with the thickness equaling to 10 nm; the second light emitting layer 42 comprises 45% TCTA: 45% Bphen: 10% Ir(ppy)₂ tmd: 0.2% Ir(mphmq)₂ (tmd) with the thickness equaling to 25 nm; the second electron transport layer comprises Bphen with the thickness equaling to 40 nm; and the cathode comprises a LiF layer with the thickness equaling to 1 nm.

In another aspect, a serially-connected white-light OLED includes: an anode, a first light emitting unit, a middle charge generating layer, a second light emitting unit, and a cathode serially connected and stacked in turn; the first light emitting unit being configured to emit blue light and the second light emitting layer being configured to emit yellow light, or both of the first and second light emitting unit being configured to emit white light; and the middle electron transport layer comprises Bphen doped with reactive metal having a work function lower than 3 eV so as to absorb electron transport material within the middle electron transport layer having a peak position larger than 490 nm or smaller than 440 nm.

In another aspect, a white-light OLED display panel includes: serially-connected white-light OLEDs stacked on a CF substrate, the serially-connected white-light OLED comprises an anode, a first light emitting unit, a middle charge generating layer, a second light emitting unit, and a cathode serially connected and stacked in turn; wherein the first light emitting unit being configured to emit blue light and the second light emitting layer being configured to emit yellow light, or both of the first and second light emitting unit being configured to emit white light; and the middle electron transport layer comprises Bphen doped with reactive metal having a work function lower than 3 eV so as to absorb electron transport material within the middle electron transport layer having a peak position larger than 490 nm or smaller than 440 nm.

In view of the above, the middle electron transport layer adopts Bphen (4.7-diphenyl-1,10-phenanthroline) doped with reactive metal having a work function lower than 3 eV so as to absorb electron transport material within the middle electron transport layer having the peak position larger than 490 nm or smaller than 440 nm. In this way, the absorbed blue light is decreased such that the blue light of the serially-connected white-light OLED is enhanced, which realizes the cool white.

### BRIEF DESCRIPTION OF THE DRAWINGS

FIG. 1 is a schematic view showing the serially-connected white-light OLED in accordance with one embodiment.

FIG. 2 is a white-light spectrum diagram of the serially-connected white-light OLED in accordance with one embodiment.

FIG. 3 is a schematic view of the white-light OLED display panel in accordance with one embodiment.

### DETAILED DESCRIPTION OF THE EMBODIMENTS

Embodiments of the invention will now be described more fully hereinafter with reference to the accompanying drawings, in which embodiments of the invention are shown.

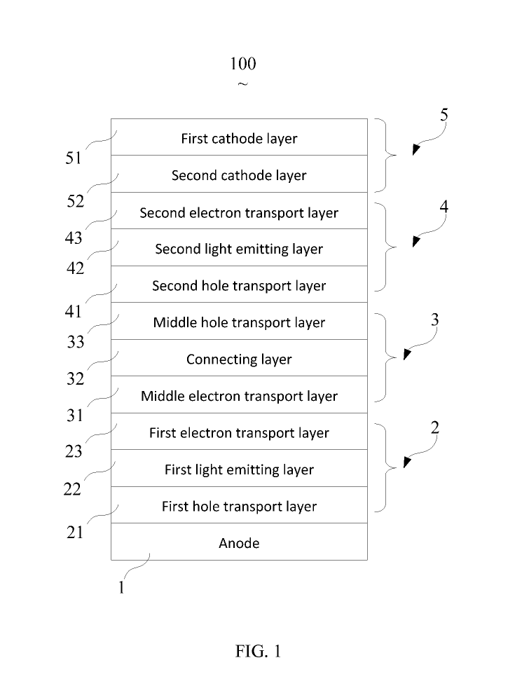

FIG. 1 is a schematic view showing the serially-connected white-light OLED in accordance with one embodiment. The serially-connected white-light OLED 100 includes an anode 1, a first light emitting unit 2, a middle charge generating layer 3, a second light emitting unit 4, and a cathode 5 that are serially connected and stacked in turn.

In one embodiment, the connecting layer includes a lowest unoccupied molecular orbital. The electronics transit from a highest occupied molecular orbital of the middle hole transport layer to the lowest unoccupied molecular orbital of the connecting layer to form a dipole. A forward voltage is applied to the anode 1 and the cathode 5, the dipole is ionized to be an electron hole and electronics due to an external electrical field. Under the electrical field, the electron hole is transmitted to the second light emitting unit 4 to compound with the electrons filled by the cathode 5 so as to emit the light. Similarly, under the electrical field, the electronics are transmitted to the first light emitting unit 2 to compound with the electron hole filled by the anode 1 so as to emit the light.

The first light emitting unit 2 includes a first hole transport layer 21, a first light emitting layer 22, and a first electron transport layer 23. The middle charge generating layer 3 includes a middle electron transport layer 31, a connecting layer 32, and a middle hole transport layer 33. The second light emitting unit 4 includes a second hole transport layer 41, a second light emitting layer 42, and a second electron transport layer 43. The cathode 5 includes a first cathode layer 51, and a second cathode layer 52. In other embodiments, the cathode 5 may be a first cathode layer 51.

In the embodiment, the first light emitting unit 2 emits blue light, and the second light emitting layer 42 emits yellow light. In other embodiments, both of the first light emitting unit 2 and the second light emitting layer 42 emit white light.

In the embodiment, the middle electron transport layer 31 adopts Bphen (4.7-diphenyl-1,10-phenanthroline) doped with reactive metal having a work function lower than 3 eV so as to absorb electron transport material within the middle electron transport layer 31 having the peak position larger than 490 nm or smaller than 440 nm.

In the embodiment, the material and the thickness range of each layers of the serially-connected white-light OLED will be described hereinafter. The anode 1 may be ITO with the thickness in a range between 60 and 80 nm. The first hole transport layer 21 adopts NPB (N,N′-2(1-naphthyl)-N,N′-diphenyl-1,1′-biphenyl-4,4′-diamine) with the thickness in a range between 50 and 70 nm. The first light emitting layer 22 may be DPVBi (4,4′-dual (2,2-diphenylethlene) biphenyl) with the thickness in a range between 20 and 30 nm. The first electron transport layer 23 may be Bphen with the thickness in a range between 8 and 12 nm. The middle electron transport layer 31 may be Bphen doped with Li, Na, K, Ru, or Cs with the thickness in a range between 8 and 12. The connecting layer 32 may be HATCN (hexanitrile hexaazatriphenylene) with the thickness in a range between 15 and 25 nm. The middle hole transport layer 33 may be NPB with the thickness in a range between 15 and 25 nm. The second hole transport layer 41 may be TCTA (4,4′,4″-3(N-carbazolyl) aniline) with the thickness in a range between 8 and 12 nm. The second light emitting layer 42 may be 45% TCTA: 45% Bphen: 10% Ir(ppy)₂tmd[iridium(III) bis(2phenylquinoline) tetramethylheptadionate]: 0.2% Ir(mphmq)₂ (tmd) [Iridium(III)bis(4-methyl-2-(3,5-dimethylphenyl)quinolinato-N,C2′)tetra-methylheptadionate] with the thickness in a range between 20 and 30 nm. The second electron transport layer 43 may be Bphen with the thickness in a range between 35 and 45 nm. The first cathode layer 51 may be Al with the thickness in a range between 90 and 110 nm. With the above configuration, the Bphen within the middle electron transport layer 31 doped with the reactive metal having work function lower than 3 eV absorbs electron transport material within the middle electron transport layer 31 having the peak position larger than 490 nm or smaller than 440 nm. In this way, the absorbed blue light is decreased so as to implement the cool white.

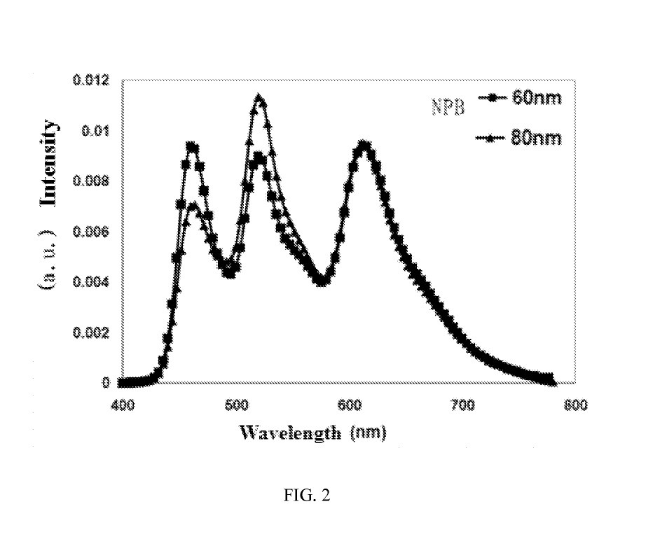

In one embodiment, the anode 1 of the serially-connected white-light OLED may be ITO with the thickness equaling to 70 nm. The first hole transport layer 21 may be NPB with the thickness equaling to 60 nm. The first light emitting layer 22 may be DPVBi with the thickness equaling to 25 nm. The first electron transport layer 23 may be Bphen with the thickness equaling to 10 nm. The middle electron transport layer 31 may be Bphen doped with Li, Na, K, Ru or Cs with the thickness equaling to 10 nm. The connecting layer 32 may be HATCH with the thickness equaling to 20 nm. The middle hole transport layer 33 may be NPB with the thickness equaling to 20 nm. The second hole transport layer 41 may be TCTA with the thickness equaling to 10 nm. The second light emitting layer 42 may be 45% TCTA: 45% Bphen: 10% Ir(ppy)₂ tmd: 0.2% Ir(mphmq)₂ (tmd) with the thickness equaling to 25 nm. The second electron transport layer 43 may be Bphen with the thickness equaling to 40 nm. The cathode 5 may be Al with the thickness equaling to 100 nm. With the above configuration, the Bphen within the middle electron transport layer 31 doped with the reactive metal having work function lower than 3 eV absorbs electron transport material within the middle electron transport layer 31 having the peak position larger than 490 nm or smaller than 440 nm. In this way, the absorbed blue light is decreased so as to implement the cool white. FIG. 2 is a white-light spectrum diagram showing the wavelength and the intensity of the serially-connected white-light OLED, after being electrified, in accordance with one embodiment. The attributes and the parameters are as described above, and the thickness of the first hole transport layer 21 may be 60 or 80 nm. It can be seen that the middle electron transport layer 31 may adopt Bphen doped with Li, Na, K, Ru or Cs that can effectively absorb the electron transport material within the middle electron transport layer 31 having the peak position larger than 490 nm or smaller than 440 nm to decrease the absorbed blue light. As such, the serially-connected white-light OLED is capable of implementing the cold white.

In other embodiments, the middle electron transport layer 31 may be alkaline-earth metal or rare earth metal. The alkaline-earth metal may include Ca, Sr or Ba. The rare earth metal may include Ce, Pr, Sm, Eu, Tb or Yb. The connecting layer 32 may be one or at least one of MoO₃, WO₃, V₂O₅, ReO₃. The cathode 5 may further include the second cathode layer 52 made by LiF with the thickness equaling to 1 nm.

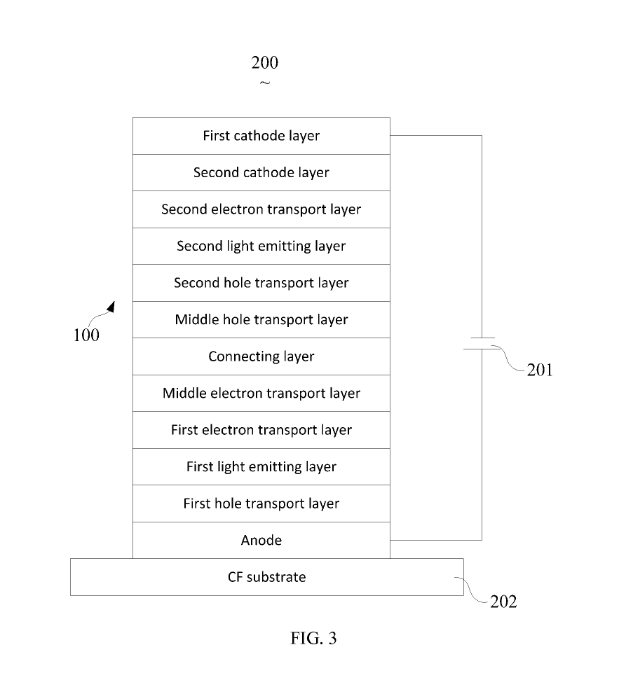

FIG. 3 is a schematic view of the white-light OLED display panel in accordance with one embodiment. The white-light OLED display panel 200 includes a power source 201, a CF substrate 202, and the above serially-connected white-light OLED 100. The light emitted by the serially-connected white-light OLED 100 emit light beams of different colors after passing the CF substrate 202.

The middle electron transport layer 31 of the serially-connected white-light OLED of the white-light OLED display panel adopts the Bphen (4.7-diphenyl-1,10-phenanthroline) doped with reactive metal having work function lower than 3 eV so as to absorb electron transport material within the middle electron transport layer 31 having the peak position larger than 490 nm or smaller than 440 nm. As such, the absorbed blue light is decreased so as to implement the cool white.

It is believed that the present embodiments and their advantages will be understood from the foregoing description, and it will be apparent that various changes may be made thereto without departing from the spirit and scope of the invention or sacrificing all of its material advantages, the examples hereinbefore described merely being preferred or exemplary embodiments of the invention.

What is claimed is:

1. A serially-connected white-light OLED, comprising:
an anode, a first light emitting unit, a middle charge generating layer, a second light emitting unit, and a cathode serially connected and stacked in turn;
the first light emitting unit being configured to emit blue light and the second light emitting layer being configured to emit yellow light, or both of the first and second light emitting unit being configured to emit white light;
the middle electron transport layer comprises Bphen doped with reactive metal having a work function lower than 3 eV so as to absorb electron transport material within the middle electron transport layer having a peak position larger than 490 nm or smaller than 440 nm;
the first light emitting unit comprises a first hole transport layer, a first light emitting layer, and a first electron transport layer;
the second light emitting unit comprises a second hole transport layer, a second light emitting layer, and a second electron transport layer;
the anode comprises ITO with a thickness equaling to 70 nm;
the first hole transport layer comprises NPB with the thickness equaling to 60 nm;
the first light emitting layer comprises DPVBi with the thickness equaling to 25 nm;
the first electron transport layer comprises Bphen with the thickness equaling to 10 nm;
the middle electron transport layer comprises Bphen doped with Li, Na, K, Ru or Cs with the thickness equaling to 10 nm;
the connecting layer comprises one or at least one of MoO₃, WO₃, V₂O₅, ReO₃ with the thickness equaling to 20 nm;
the middle hole transport layer comprises NPB with the thickness equaling to 20 nm;
the second hole transport layer comprises TCTA with the thickness equaling to 10 nm;
the second light emitting layer 42 comprises 45% TCTA: 45% Bphen: 10% Ir(ppy)₂ tmd: 0.2% Ir(mphmq)₂ (tmd) with the thickness equaling to 25 nm;
the second electron transport layer comprises Bphen with the thickness equaling to 40 nm; and
the cathode comprises a LiF layer with the thickness equaling to 1 nm.

2. A serially-connected white-light OLED, comprising:
an anode, a first light emitting unit, a middle charge generating layer, a second light emitting unit, and a cathode serially connected and stacked in turn;
the first light emitting unit being configured to emit blue light and the second light emitting layer being configured to emit yellow light, or both of the first and second light emitting unit being configured to emit white light; and
the middle electron transport layer comprises Bphen doped with reactive metal having a work function lower than 3 eV so as to absorb electron transport material within the middle electron transport layer having a peak position larger than 490 nm or smaller than 440 nm.

3. The serially-connected white-light OLED as claimed in claim 2, wherein:
the first light emitting unit comprises a first hole transport layer, a first light emitting layer, and a first electron transport layer; and
the second light emitting unit comprises a second hole transport layer, a second light emitting layer, and a second electron transport layer.

4. The serially-connected white-light OLED as claimed in claim 3, wherein:
the anode comprises ITO with a thickness in a range between 60 and 80 nm;
the first hole transport layer comprises NPB with the thickness in a range between 50 and 70 nm;
the first light emitting layer comprises DPVBi with the thickness in a range between 20 and 30 nm;
the first electron transport layer comprises Bphen with the thickness in a range between 8 and 12 nm;
the middle electron transport layer comprises Bphen doped with Li, Na, K, Ru or Cs with the thickness in a range between 8 and 12;
the connecting layer comprises HATCH with the thickness in a range between 15 and 25 nm;
the middle hole transport layer comprises NPB with the thickness in a range between 15 and 25 nm;
the second hole transport layer comprises TCTA with the thickness in a range between 8 and 12 nm;
the second light emitting layer 42 comprises 45% TCTA: 45% Bphen: 10% Ir(ppy)₂ tmd: 0.2%Ir(mphmq)2 (tmd) with the thickness in a range between 20 and 30 nm;
the second electron transport layer comprises Bphen with the thickness in a range between 35 and 45 nm; and
the cathode comprises Al with the thickness in a range between 90 and 110 nm.

5. The serially-connected white-light OLED as claimed in claim 3, wherein:
the anode comprises ITO with a thickness equaling to 70 nm;
the first hole transport layer comprises NPB with the thickness equaling to 60 nm;
the first light emitting layer comprises DPVBi with the thickness equaling to 25 nm;
the first electron transport layer comprises Bphen with the thickness equaling to 10 nm;
the middle electron transport layer comprises Bphen doped with Li, Na, K, Ru or Cs with the thickness equaling to 10 nm;
the connecting layer comprises one or at least one of MoO₃, WO₃, V₂O₅, ReO₃ with the thickness equaling to 20 nm;
the middle hole transport layer comprises NPB with the thickness equaling to 20 nm;
the second hole transport layer comprises TCTA with the thickness equaling to 10 nm;
the second light emitting layer 42 comprises 45% TCTA: 45% Bphen: 10% Ir(ppy)₂ tmd: 0.2% Ir(mphmq)₂ (tmd) with the thickness equaling to 25 nm;
the second electron transport layer comprises Bphen with the thickness equaling to 40 nm; and
the cathode comprises Al with the thickness equaling to 100 nm.

6. The serially-connected white-light OLED as claimed in claim 4, wherein the middle electron transport layer comprises alkaline-earth metal or rare earth metal, the alkaline-earth metal comprises Ca, Sr or Ba, and the rare earth metal comprises Ce, Pr, Sm, Eu, Tb or Yb.

7. The serially-connected white-light OLED as claimed in claim 5, wherein the middle electron transport layer may be alkaline-earth metal or rare earth metal, the alkaline-earth metal comprises Ca, Sr or Ba, and the rare earth metal comprises Ce, Pr, Sm, Eu, Tb or Yb.

8. The serially-connected white-light OLED as claimed in claim 4, wherein the connecting layer comprises one or at least one of MoO₃, WO₃, V₂O₅, ReO₃.

9. The serially-connected white-light OLED as claimed in claim 5, wherein the connecting layer comprises one or at least one of MoO₃, WO₃, V₂O₅, ReO₃.

10. The serially-connected white-light OLED as claimed in claim 5, wherein the cathode comprises a LiF layer with the thickness equaling to 1 nm.

11. A white-light OLED display panel, comprising:
serially-connected white-light OLEDs stacked on a CF substrate, the serially-connected white-light OLED comprises an anode, a first light emitting unit, a middle charge generating layer, a second light emitting unit, and a cathode serially connected and stacked in turn;
wherein the first light emitting unit being configured to emit blue light and the second light emitting layer being configured to emit yellow light, or both of the first and second light emitting unit being configured to emit white light; and
the middle electron transport layer comprises Bphen doped with reactive metal having a work function lower than 3 eV so as to absorb electron transport material within the middle electron transport layer having a peak position larger than 490 nm or smaller than 440 nm.

12. The white-light OLED display panel as claimed in claim 11, wherein:
the first light emitting unit comprises a first hole transport layer, a first light emitting layer, and a first electron transport layer; and
the second light emitting unit comprises a second hole transport layer, a second light emitting layer, and a second electron transport layer.

13. The white-light OLED display panel as claimed in claim 12, wherein:
the anode comprises ITO with a thickness in a range between 60 and 80 nm;
the first hole transport layer comprises NPB with the thickness in a range between 50 and 70 nm;
the first light emitting layer comprises DPVBi with the thickness in a range between 20 and 30 nm;
the first electron transport layer comprises Bphen with the thickness in a range between 8 and 12 nm;
the middle electron transport layer comprises Bphen doped with Li, Na, K, Ru or Cs with the thickness in a range between 8 and 12;
the connecting layer comprises HATCH with the thickness in a range between 15 and 25 nm;
the middle hole transport layer comprises NPB with the thickness in a range between 15 and 25 nm;
the second hole transport layer comprises TCTA with the thickness in a range between 8 and 12 nm;
the second light emitting layer 42 comprises 45% TCTA: 45% Bphen: 10% Ir(ppy)₂ tmd: 0.2% Ir(mphmq)₂ (tmd) with the thickness in a range between 20 and 30 nm;
the second electron transport layer comprises Bphen with the thickness in a range between 35 and 45 nm; and
the cathode comprises Al with the thickness in a range between 90 and 110 nm.

14. The serially-connected white-light OLED as claimed in claim 12, wherein:
the anode comprises ITO with a thickness equaling to 70 nm;
the first hole transport layer comprises NPB with the thickness equaling to 60 nm;
the first light emitting layer comprises DPVBi with the thickness equaling to 25 nm;
the first electron transport layer comprises Bphen with the thickness equaling to 10 nm;
the middle electron transport layer comprises Bphen doped with Li, Na, K, Ru or Cs with the thickness equaling to 10 nm;
the connecting layer comprises one or at least one of MoO₃, WO₃, V₂O₅, ReO₃ with the thickness equaling to 20 nm;
the middle hole transport layer comprises NPB with the thickness equaling to 20 nm;
the second hole transport layer comprises TCTA with the thickness equaling to 10 nm;
the second light emitting layer 42 comprises 45% TCTA: 45% Bphen: 10% Ir(ppy)₂ tmd: 0.2% Ir(mphmq)₂ (tmd) with the thickness equaling to 25 nm;
the second electron transport layer comprises Bphen with the thickness equaling to 40 nm; and
the cathode comprises Al with the thickness equaling to 100 nm.

15. The white-light OLED display panel as claimed in claim 13, wherein the middle electron transport layer comprises alkaline-earth metal or rare earth metal, the alkaline-earth metal comprises Ca, Sr or Ba, and the rare earth metal comprises Ce, Pr, Sm, Eu, Tb or Yb.

16. The white-light OLED display panel as claimed in claim 14, wherein the middle electron transport layer comprises alkaline-earth metal or rare earth metal, the alkaline-earth metal comprises Ca, Sr or Ba, and the rare earth metal comprises Ce, Pr, Sm, Eu, Tb or Yb.

17. The white-light OLED display panel as claimed in claim 13, wherein the connecting layer comprises one or at least one of MoO₃, WO₃, V₂O₅, ReO₃.

18. The white-light OLED display panel as claimed in claim 14, wherein the connecting layer comprises one or at least one of MoO₃, WO₃, V₂O₅, ReO₃.

19. The white-light OLED display panel as claimed in claim 14, wherein the cathode comprises a LiF layer with the thickness equaling to 1 nm.
